(19) United States
(12) Patent Application Publication
(10) Pub. No.: US 2026/0052662 A1
(43) Pub. Date: Feb. 19, 2026

(54) METHOD OF PROVIDING AN ELECTRICALLY CONDUCTIVE LAYER TO A PLASTIC HOUSING BY INSERTION MOLDING OF A CONDUCTIVE FILM

(71) Applicant: Aptiv Technologies AG, Schaffhausen (CH)

(72) Inventors: Michal CIESZYNSKI, Kraków (PL); Pawel KWIATKOWSKI, Kraków (PL)

(21) Appl. No.: 19/251,108

(22) Filed: Jun. 26, 2025

(30) Foreign Application Priority Data
Aug. 14, 2024 (EP) 24194646.6

(51) Int. Cl. H05K 9/00; B29C 45/14; B29K 705/02; B29L 31/34

(52) U.S. Cl. CPC H05K 9/002; B29C 45/1418; B29K 2705/02; B29K 2995/0005; B29L 2031/3406

(57) ABSTRACT

A method of providing an electrically conductive layer to a plastic splice housing for electromagnetically shielded cable harnesses includes providing an electrically conductive film and a mold, inserting the film into the mold, and injecting plastic into the mold so that the plastic bonds with the electrically conductive film, thereby forming an integrated conductive layer on the plastic housing suitable for electromagnetic shielding.

### CROSS-REFERENCE TO RELATED APPLICATION

This application claims the benefit of and priority to European Application No. 24194646.6 filed with the European Patent Office on Aug. 14, 2024, the contents of which are incorporated by reference herein.

### TECHNICAL FIELD

The present disclosure generally relates to a method of providing an electrically conductive layer to a plastic housing, and it relates to a splice housing, a cable harness and a vehicle.

### BACKGROUND

Electromagnetic interference (EMI) can cause significant disruptions in electronic devices and systems, particularly by using plastic housings used in cable harnesses, leading to malfunctions or degradation of performance. To mitigate EMI, housings of electronic components are often made of conductive materials to shield them from external electromagnetic fields.

Traditional methods of providing electromagnetic shielding might include applying conductive coatings or metallic layers to the exterior of plastic housings. However, these methods can be labor-intensive, costly, and subject to wear and degradation over time. Injection molding conductive materials directly into plastic housings presents a more efficient and durable solution, combining the structural benefits of plastic with the conductive properties necessary for effective EMI shielding.

It is disadvantageous that existing methods often involve multiple steps, including post-molding applications of conductive coatings, which can be time-consuming and may not provide a robust or long-lasting solution. Additionally, ensuring complete and uniform coverage of conductive material on complex three-dimensional shapes can be challenging with traditional techniques. Thus, there is a demand for improved methods of manufacturing splice housings with EMI shielding.

In view of the foregoing, there is a need for improved methods of manufacturing splice housings with EMI shielding. It is thus an object of the present disclosure to overcome some or all the deficiencies of the prior art.

### SUMMARY

An aspect of the disclosure relates to a method of providing an electrically conductive layer to a plastic housing, in particular a splice housing for electromagnetically shielded cable harnesses, including the steps of:
a) providing an electrically conductive film and a mold;
b) inserting the film into the mold; and
c) injection molding plastic into the mold so that the injected plastic bonds with the electrically conductive film.

Such a method could be used to create housings for high-performance automotive cable systems that require electromagnetic interference (EMI) shielding. By integrating the conductive film during the injection molding process, the resulting plastic housing is both robust and capable of shielding sensitive electronic components from electromagnetic interference. This approach streamlines production, reduces the need for post-processing steps like applying conductive coatings, and ensures a strong bond between the plastic and the conductive layer, enhancing durability and performance.

This method can be improved when the mold has a 3D-contour, and the film conforms to the contour during step c) due to the injected plastic.

Such a method can be used to produce complex-shaped housings for electronic devices. The mold is designed with complex 3D contours to match the final product's shape. As the plastic is injected, the conductive film is pressed and molded to fit these contours perfectly. This ensures that the entire surface area of the housing is covered with the conductive layer, providing consistent and effective electromagnetic shielding. The advantage of this approach is the ability to create detailed and precise shapes without compromising the integrity of the conductive layer, leading to higher quality and more reliable electronic housings.

Further improvement is achieved when before step b), the film is pre-formed to at least partially conform to the contour of the mold.

Such a pre-forming step can ensure that the film already has the basic shape of the final product, reducing the risk of wrinkles or misalignment during the injection molding process. The main advantage of pre-forming the film is improved accuracy and consistency in the final product's conductive layer, leading to better electromagnetic shielding performance and a more aesthetically pleasing finish. Additionally, this method can reduce manufacturing time and costs by minimizing adjustments needed during molding.

Further improvement is achieved when the film is an in-mold label.

Such an in-mold label not only provides the required conductive properties but can also include additional information, such as branding or functional graphics. The use of an in-mold label streamlines the production process by combining the labeling and conductive layer application into a single step. This approach enhances the durability of the label, ensuring it remains intact and functional throughout the product's lifecycle. Moreover, it provides a high-quality, finished appearance without the need for additional labeling or printing steps after molding.

Further improvement is achieved when the film includes aluminum.

Such a film including aluminum can ensure efficient electromagnetic shielding while adding minimal weight to the plastic housing. This is beneficial for applications where weight reduction is important. Additionally, aluminum durability and resistance to corrosion enhance the longevity and reliability of the product. This method leverages aluminum's properties to produce high-performance, electromagnetically shielded housings with robust and lightweight characteristics.

Further improvement is achieved when the film has a thickness in the range of 0.1 mm to 5 mm, preferably in the range 0.1 mm to 4 mm, more preferably in the range 0.2 mm to 3 mm, most preferably 0.35 mm.

Such a specific thickness of, for instance 3.5 mm can provide an optimal balance between flexibility and durability, ensuring that the film can conform to the mold's contours while maintaining its structural integrity and conductivity. A film within this thickness range ensures efficient electromagnetic shielding without adding unnecessary bulk to the plastic housing. This precision in thickness specification allows for enhanced performance and reliability in demanding applications, such as in electronics enclosures and automotive components, where space and weight are important factors.

Further improvement is achieved when after step c) the ratio of the thickness of the plastic layer to the thickness of the electrically conductive film is in the range 1:1 to 10:1, preferably in the range 3:1 to 7:1, most preferably 5:1.

According to such a method, after the plastic has been injection molded and bonded to the aluminum conductive film, the thickness of the plastic layer is five times that of the conductive film. Such a specific ratio can ensure that the plastic housing provides adequate mechanical strength and durability while maintaining effective electromagnetic shielding. A ratio of 5:1 can strike a balance between robust structural support and lightweight design. This optimized ratio helps achieve high performance and reliability in the final product, ensuring that it meets both mechanical and shielding requirements efficiently.

Further improvement is achieved when the film includes fixation means, configured to form a form fit connection with the plastic, preferably wherein the fixation means includes teeth.

Such a type of teeth can be designed to embed into the plastic during the injection molding process, creating a firm mechanical bond between the film and the plastic. This form fit connection enhances the adhesion between the layers, preventing delamination and ensuring long-term durability. This method is useful in applications where the housing may be subjected to mechanical stress or thermal expansion, such as in automotive environments. The teeth provide additional anchoring points, leading to improved structural integrity and reliability of the final product.

Further improvement is achieved when the film includes a perforation.

Such a conductive film can be perforated with small holes throughout its surface. These perforations allow the injected plastic to flow through the film, creating a stronger bond between the plastic and the film as it solidifies. The perforations also enhance flexibility, making it easier for the film to conform to complex mold shapes. This method is advantageous for applications requiring a highly durable and flexible conductive layer, such as in complex electronic housings or automotive components. The perforations ensure robust adhesion, preventing separation of the layers under mechanical stress and enhancing the overall durability and performance of the product.

Further improvement is achieved when after step c) the film covers completely the contour of the mold.

Such a conductive film could be designed to entirely cover the 3D contours of the mold. After the injection molding process, the film forms a continuous layer over the entire surface of the plastic housing. This ensures that the entire housing benefits from the conductive properties of the film, providing comprehensive electromagnetic shielding. Additionally, complete coverage enhances the aesthetic appeal of the final product, providing a uniform surface without gaps or exposed plastic areas. This leads to a more reliable and visually appealing product, meeting both functional and design requirements effectively.

Instead, further improvement could also be achieved, when the film after step c) does not completely cover the contour of the mold.

In such a method, the conductive film can be strategically placed to cover only specific areas of the mold's contour. After the injection molding process, the film adheres to designated sections of the plastic housing, leaving other areas uncovered. This approach allows for targeted electromagnetic shielding, which is useful in applications where shielding is only needed in certain regions, such as around important electronic components. Additionally, this method can reduce material costs and weight, as less conductive film is used. The selective coverage also provides design flexibility, enabling the creation of housings with varied functional and aesthetic requirements.

Another embodiment is a splice housing for electromagnetically shielded cable harnesses, including two halves formed by a method described precedingly.

Such a splice housing for electromagnetically shielded cable harnesses is made up of two halves created using the described method. Each half could be for instance produced by injection molding plastic onto an aluminum conductive film. These halves are then joined to encase the cable splices, ensuring complete electromagnetic shielding. The use of the conductive film integrated during molding provides great protection against electromagnetic interference, enhancing the reliability of the cable harnesses. Additionally, the robust bond between the film and plastic ensures long-lasting durability, making the splice housing suitable for demanding environments in automotive applications. This method allows for precise manufacturing of the splice housing, ensuring a high-quality, effective shield against electromagnetic interference.

Another embodiment is a cable harness, including a splice housing described above.

Such a cable harness incorporates a splice housing made up of two halves created using the specified method. This splice housing provides comprehensive electromagnetic shielding for the cable harness, protecting the enclosed cables from external electromagnetic interference. The use of the conductive film ensures that the housing maintains its shielding effectiveness over time, even in harsh environments. This integration enhances the overall performance and reliability of the cable harness, making it ideal for applications where robust EMC is necessary. Additionally, the precisely manufactured splice housing contributes to the structural integrity and longevity of the cable harness.

Another embodiment is a vehicle, preferably an electric or hybrid vehicle, including a cable harness described above.

Such a harness can provide great electromagnetic shielding, protecting the vehicle's sensitive electronic systems from electromagnetic interference. By ensuring reliable operation of the vehicle's electronics, the cable harness enhances overall performance and safety. The advanced shielding is beneficial in electric and hybrid vehicles, where electronic components are important for efficient and effective operation. This integration supports the vehicle's durability and long-term functionality, contributing to a higher-quality, more reliable transportation solution.

Another embodiment is a splice housing for an electromagnetically shielded cable harnesses, the splice housing including an outer housing made from injection molded plastic, and an interior conductive film, bonded to the interior walls of the outer housing by the injection molding process.

Such a splice housing for an electromagnetically shielded cable harness includes an outer shell made of injection molded plastic and an interior layer of conductive film. The conductive film is integrated and securely bonded to the inner walls of the plastic shell during the injection molding process. This design provides robust electromagnetic shielding by ensuring the conductive film is firmly attached and covers the necessary areas. The plastic outer shell offers mechanical protection and structural support, while the conductive film prevents electromagnetic interference from affecting the enclosed cables. This construction method results in a durable, reliable splice housing that effectively combines mechanical strength with electromagnetic shielding.

### BRIEF DESCRIPTION OF THE DRAWINGS

In the following, preferred embodiments of the disclosure are disclosed by reference to the accompanying figures.

FIG. 1 illustrates an isometric view of a splice housing half according to some embodiments.

FIGS. 2a to 2c show steps of the injection molding a film in the splice housing half according to some embodiments.

FIG. 3 shows a top view of the splice housing half of FIG. 1 according to some embodiments.

### DETAILED DESCRIPTION

In the following, preferred embodiments of the present disclosure are described in detail with respect to the figures.

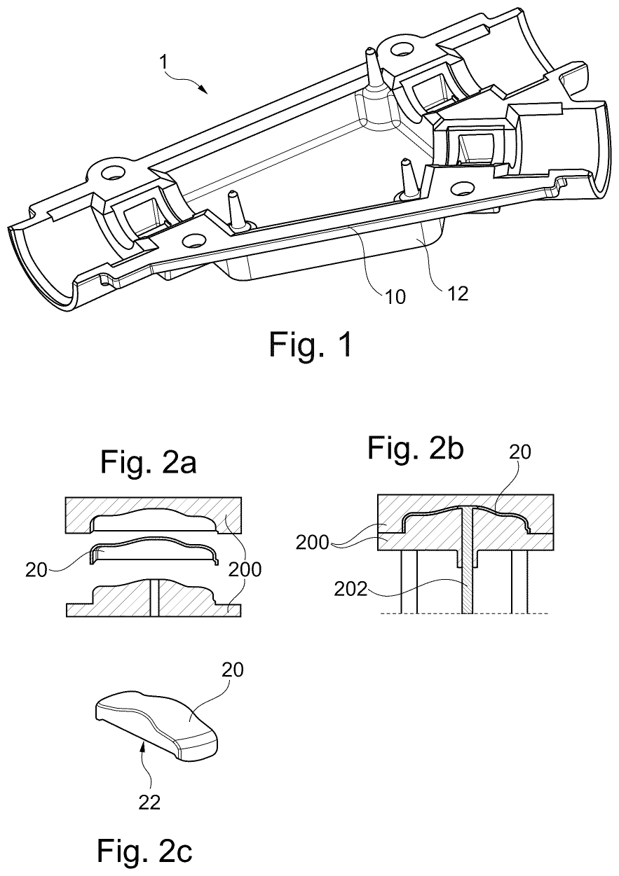

FIG. 1 illustrates a half of a splice housing. The splice housing half 1 has its inner surface completely covered by the conductive film 10, which adheres to the plastic housing 12, formed by injection molding. The skilled person will understand that a correspondingly shaped second half may be connected to form a complete splice housing.

The conductive film 10 completely covers the inner surface, thus ensuring full electromagnetic shielding. The bonding of the film to the plastic housing 12 during the injection molding process can create a strong, durable connection. Such a continuous integration of the conductive film can enhance the overall performance and reliability of the splice housing. The method also simplifies manufacturing by combining film application and housing formation in a single step.

FIGS. 2a to 2c show steps of the injection molding the film. In FIG. 2a, a pre-formed conductive film 20 is inserted into the mold 200. In FIG. 2b, the mold 200 is closed and molten plastic 202 is introduced into the mold via injection molding, thus establishing a bond between the film 20 and the plastic 202. FIG. 2c shows the demolded housing 22 with a conductive film 20 on its outer side.

With such a process the injection molding process can ensure precise application and bonding of the conductive film.
Step A: Inserting the pre-formed conductive film 20 into mold 200 can ensure that the film is correctly positioned before plastic injection.
Step B: Closing the mold 200 and injecting molten plastic 202 bonds the film 20 to the plastic 202 as it solidifies, creating a strong, uniform layer.
Step C: The demolded housing 22 showcases the conductive film 20 securely attached to its outer side, providing effective electromagnetic shielding. Such a method offers several advantages, including enhanced durability of the bond between the film and the plastic, simplified manufacturing by combining film application and molding in one step, and the ability to produce complex shapes with an integrated electromagnetic shielding.

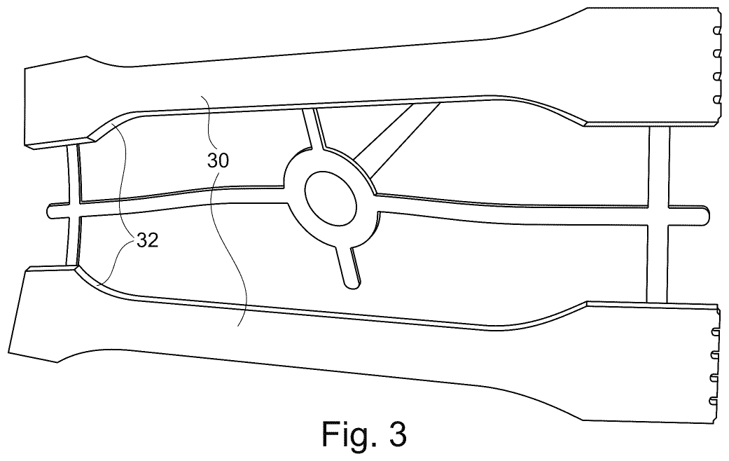

FIG. 3 depicts a plastic part provided with a conductive film. The plastic 32 has an adhering conductive film 30. FIG. 3 illustrates the effectiveness of the bonding process. The plastic part 32 is uniformly covered by conductive film 30, indicating a strong adhesion between the two materials.

While the invention has been described with reference to an exemplary embodiment(s), it will be understood by those skilled in the art that various changes may be made, and equivalents may be substituted for elements thereof without departing from the scope of the invention. In addition, many modifications may be made to configure a particular situation or material to the teachings of the invention without departing from the essential scope thereof. Therefore, it is intended that the invention is not limited to the disclosed embodiment(s), but that the invention will include all embodiments falling within the scope of the appended claims.

As used herein, ‘one or more’ includes a function being performed by one element, a function being performed by more than one element, e.g., in a distributed fashion, several functions being performed by one element, several functions being performed by several elements, or any combination of the above.

It will also be understood that, although the terms first, second, etc., are, in some instances, used herein to describe various elements, these elements should not be limited by these terms. These terms are only used to distinguish one element from another. For example, a first contact could be termed a second contact, and, similarly, a second contact could be termed a first contact, without departing from the scope of the various described embodiments. The first contact and the second contact are both contacts, but they are not the same contact.

The terminology used in the description of the various described embodiments herein is for the purpose of describing particular embodiments only and is not intended to be limiting. As used in the description of the various described embodiments and the appended claims, the singular forms “a”, “an”, and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

Additionally, while terms of ordinance or orientation may be used herein these elements should not be limited by these terms. All terms of ordinance or orientation, unless stated otherwise, are used for purposes distinguishing one element from another, and do not denote any particular order, order of operations, direction or orientation unless stated otherwise.

Listing of Reference Numbers

| | |
|---|---|
| 1 | splice housing half |
| 10, 20, 30 | conductive film |
| 12, 22 | plastic housing |
| 32 | plastic |
| 200 | mold |
| 202 | molten plastic |

1. A method of providing an electrically conductive layer to a plastic housing, in particular a splice housing for electromagnetically shielded cable harnesses, the method comprising the steps of:
a) providing an electrically conductive film and a mold;
b) inserting the film into the mold; and
c) injecting plastic into the mold so that the plastic bonds with the electrically conductive film.

2. The method according to claim 1, wherein the mold has a 3D-contour and wherein the film conforms to the 3D-contour during step c) due to the injected plastic.

3. The method according to claim 2, wherein the film is pre-formed to at least partially conform to the 3D-contour of the mold prior to step b).

4. The method according to claim 2, wherein after step c) the film completely covers the 3D-contour of the mold.

5. The method according to claim 2, wherein the film after step c) does not completely cover the 3D-contour of the mold.

6. The method according to claim 1, wherein the film is an in-mold label.

7. The method according to claim 1, wherein the film comprises aluminum.

8. The method according to claim 1, wherein the film has a thickness in a range of 0.1 mm to 5 mm.

9. The method according to claim 1, wherein a ratio of a thickness of the plastic to a thickness of the electrically conductive film is in a range 1:1 to 10:1 after step c).

10. The method according to claim 9, wherein the ratio of the thickness of the plastic to the thickness of the electrically conductive film is in a range 3:1 to 7:1 after step c).

11. The method according to claim 10, wherein the ratio of the thickness of the plastic to the thickness of the electrically conductive film is 5:1 after step c).

12. The method according to claim 1, wherein the film comprises fixation means configured to form a form fit connection with the plastic.

13. The method according to claim 12, wherein the fixation means comprises teeth.

14. The method according to claim 1, wherein the film comprises a perforation.

15. A splice housing for electromagnetically shielded cable harnesses, comprising two halves formed by a method comprising:
a) providing an electrically conductive film and a mold;
b) inserting the film into the mold; and
c) injecting plastic into the mold so that the plastic bonds with the electrically conductive film.

16. A cable harness, comprising a splice housing according to claim 15.

17. A vehicle comprising a cable harness according to claim 16.

18. A splice housing for an electromagnetically shielded cable harnesses, comprising:
an outer housing made from injection molded plastic; and
an interior conductive film, bonded to interior walls of the outer housing by an injection molding process.
